(19) United States
(12) Patent Application Publication
(10) Pub. No.: US 2023/0015599 A1
(43) Pub. Date: Jan. 19, 2023

(54) DATA MANAGEMENT SYSTEM, MANAGEMENT METHOD, AND STORAGE MEDIUM

(71) Applicant: TOPCON CORPORATION, Tokyo (JP)

(72) Inventors: Atsushi DOJI, Tokyo (JP); Toshio YAMADA, Tokyo (JP); Nobuyuki NISHITA, Tokyo (JP); Satoshi YANOBE, Tokyo (JP); Junki KANEKO, Tokyo (JP)

(21) Appl. No.: 17/783,215

(22) PCT Filed: Nov. 27, 2020
(86) PCT No.: PCT/JP2020/044195

§ 371 Date: Jun. 7, 2022

(30) Foreign Application Priority Data
Dec. 23, 2019 (JP) 2019-231284

(51) Int. Cl. G06F 30/12; G06Q 50/08; G06F 30/13

(52) U.S. Cl. CPC G06F 30/12; G06Q 50/08; G06F 30/13

(57) ABSTRACT

A management system includes a design database of construction members, a measurement database of the construction members, a construction database recording construction data of the construction members, a construction member selecting unit, a peripheral member selecting unit, a model creating unit configured to create a design model of the construction member and a measurement model of the peripheral member, a corrected model creating unit configured to create a design corrected model by synthesizing the design model and the measurement model, and a corrected construction plan creating unit configured to select a construction designated member based on the design corrected model, and record, with respect to the construction designated member, coordinates and a shape of the design corrected model as construction designated member coordinates and a construction designated member shape, and construction content of the construction designated member as construction inspection content, in a corrected construction plan database.

### TECHNICAL FIELD

The present invention relates to a system, method, and program for managing data for design and construction of a construction object.

### BACKGROUND ART

In recent years, in the field of construction, utilization of a 3D model called BIM (Building Information Modeling) has been promoted. BIM has been increasingly utilized at design sites, that is, planning, architectural design, facility design, design analysis, execution design, construction planning, and component manufacturing. For example, Patent Literature 1 discloses a technology for utilizing BIM at manufacturing sites of members at a plant.

### CITATION LIST

### Patent Literature

Patent Literature 1: Japanese Published Unexamined Patent Application No. 2019-21190

### SUMMARY OF INVENTION

### Technical Problem

However, at construction sites, utilization of BIM has been delayed, and a technology for coordinating an actual construction status with BIM has been desired. In addition, it frequently occurs that on-site construction processes do not proceed according to original designs, and therefore, data management to reflect an actual construction status in upstream drawings and turn it over to downstream construction processes is also desired. Furthermore, at a construction site, there are some members that are not included in design BIM but are necessary for construction, and data management to consider such members including their influences is also desired.

The present invention was made in view of these problems, and an object thereof is to realize data management to reflect an actual construction status in the upstream or downstream process.

### Solution to Problem

In order to solve the problems described above, a management method according to an aspect of the present invention includes, by transmitting and receiving information to and from a design database recording design data of construction members constituting a construction object, a measurement database recording measurement data of the construction members, and a construction database storing construction data of the construction members, a step (A) of selecting a construction member from the construction database, a step (B) of creating a design model of the construction member from design data of the construction member in the design database, a step (C) of selecting a peripheral member peripheral to the construction member from the design database, a step (D) of creating a measurement model of the peripheral member from measurement data of the peripheral member in the measurement database, a step (E) of creating a design corrected model by synthesizing the design model and the measurement model, a step (F) of selecting a construction designated member for which a construction plan is corrected based on the design corrected model, and a step (G) of recording, with respect to the construction designated member, coordinates and a shape of the design corrected model as construction designated member coordinates and a construction designated member shape, and construction content of the construction designated member as construction inspection content, in the corrected construction plan database.

In the aspect described above, it is also preferable that, further, by transmitting and receiving information to and from a member database recording member basic data of the construction members, before the step (E), whether the construction member and the peripheral member are movable members is determined by referring to the member database, and when the member is determined to be unmovable, the design corrected model is created in the step (E), and when the member is determined to be movable, movability information of the movable member is read from the member database and a movable model of the movable member is created, and a design corrected model is created by synthesizing the design model or the measurement model with the movable model, and the processing shifts to the step (F), and in the step (G), by further referring to the member database, construction influenced portion information based on the movability information of the movable member is recorded in the corrected construction plan database.

In order to solve the problems described above, a management method according to another aspect of the present invention includes, by transmitting and receiving information to and from a design database recording design data of construction members constituting a construction object, a measurement database recording measurement data of the construction members, a member database recording member basic data of the construction members, and a construction database storing construction data of the construction members, a step (L) of selecting a construction member from the construction database, a step (M) of selecting a peripheral member peripheral to the construction member from the design database, a step (N) of creating a measurement model of the peripheral member based on measurement data in the measurement database, a step (0) of creating a basic shape model of the construction member from the member basic data in the member database and the construction data in the construction database, a step (P) of creating a design corrected model by synthesizing the measurement model and the basic shape model, a step (Q) of selecting a construction designated member for which a construction plan is corrected based on the design corrected model, and a step (R) of recording, with respect to the construction designated member, coordinates and a shape of the design corrected model as construction designated member coordinates and a construction designated member shape, and construction content of the construction designated member as construction inspection content, in a corrected construction plan database.

In the aspect described above, it is also preferable that, further, before the step (P), whether the construction member and the peripheral member are movable members is determined by referring to the member database, and when the member is determined to be unmovable, the design corrected model is created in the step (P), and when the member is determined to be movable, movability information of the movable member is read from the member database, a movable model of the movable member is created, a design corrected model is created by synthesizing the measurement model, the basic shape model, and the movable model, and the processing shifts to the step (Q), and in the Step (R), by further referring to the member database, influenced portion information based on the movability information of the movable member is recorded in the corrected construction plan database.

In the aspect described above, it is also preferable that the management method further includes a step of writing the construction designated member coordinates and the construction designated member shape of the construction designated member recorded in the corrected construction plan database over member coordinates and a member shape linked by member identification information of the construction designated member in the design database.

In the aspect described above, it is also preferable that the management method further includes a step of newly adding the construction designated member, the construction designated member coordinates, and the construction designated member shape recorded in the corrected construction plan database into the design database.

A management program describing the management method according to the aspect described above as a computer program and enabling execution of the management method is also preferable.

In order to solve the problems described above, a management system according to an aspect of the present invention includes a design database recording design data of construction members constituting a construction object, a measurement database recording measurement data of the construction members, a construction database storing construction data of the construction members, a construction member selecting unit configured to select a construction member from the construction database, a peripheral member selecting unit configured to select a peripheral member peripheral to the construction member from the design database, a model creating unit configured to create a design model of the construction member from the design data of the construction member, and a measurement model of the peripheral member from the measurement data of the peripheral member, a corrected model creating unit configured to create a design corrected model by synthesizing the design model and the measurement model, and a corrected construction plan creating unit configured to select a construction designated member for which a construction plan is corrected based on the design corrected model, and record, with respect to the construction designated member, coordinates and a shape of the design corrected model as construction designated member coordinates and a construction designated member shape, and construction content of the construction designated member as construction inspection content, in a corrected construction plan database.

In the aspect described above, it is also preferable that the management system further includes a member database recording member basic data of the construction members, and a member movability determining unit configured to determine whether the construction member and the peripheral member are movable members by referring to the member database, and when determining that the member is movable, read movability information of the movable member from the member database and create a movable model of the movable member, wherein the corrected model creating unit creates a design corrected model by synthesizing the design model or the measurement model with the movable model, and the corrected construction plan creating unit refers to the member database and further records construction influenced portion information based on the movability information of the movable member in the corrected construction plan database.

In order to solve the problems described above, a management system according to another aspect of the present invention includes a design database recording design data of construction members constituting a construction object, a measurement database recording measurement data of the construction members, a member database recording member basic data of the construction members, a construction database storing construction data of the construction members, a construction member selecting unit configured to select a construction member from the construction database, a peripheral member selecting unit configured to select a peripheral member peripheral to the construction member from the design database, a model creating unit configured to create a measurement model of the peripheral member based on the measurement data in the measurement database, a basic shape model creating unit configured to create a basic shape model of the construction member from the member basic data in the member database and the construction data in the construction database, a corrected model creating unit configured to create a design corrected model by synthesizing the measurement model and the basic shape model, and a corrected construction plan creating unit configured to select a construction designated member for which a construction plan is corrected based on the design corrected model, and record, with respect to the construction designated member, coordinates and a shape of the design corrected model as construction designated member coordinates and a construction designated member shape, and construction content of the construction designated member as construction inspection content, in a corrected construction plan database.

In the aspect described above, it is also preferable that the management system further includes a member movability determining unit configured to determine whether the construction member and the peripheral member are movable members by referring to the member database, and when determining that the member is movable, read movability information of the movable member from the member database and create a movable model of the movable member, wherein the corrected model creating unit creates a design corrected model by synthesizing the measurement model, the basic shape model, and the movable model, and the corrected construction plan creating unit refers to the member database and further records construction influenced portion information based on the movability information of the movable member in the corrected construction plan database.

In the aspect described above, it is also preferable that the management system further includes a corrected construction plan reflecting unit configured to write the construction designated member coordinates and the construction designated member shape of the construction designated member recorded in the corrected construction plan database over member coordinates and a member shape linked by member identification information of the construction designated member in the design database.

In the aspect described above, it is also preferable that the management system further includes a corrected construction plan reflecting unit configured to newly add the construction designated member, the construction designated member coordinates, and the construction designated member shape recorded in the corrected construction plan database into the design database.

### Advantageous Effects of Invention

According to the data management system, management method, and management program of the present invention, data management to reflect an actual construction status in the upstream or downstream data is realized.

### BRIEF DESCRIPTION OF DRAWINGS

FIG. 1 is a block diagram illustrating a configuration of a management system according to a first embodiment of the present invention.

FIG. 2 is a diagram illustrating an example of a design database according to the management system.

FIG. 3 is a diagram illustrating an example of a measurement database according to the management system.

FIG. 4 is a diagram illustrating an example of a construction database according to the management system.

FIG. 5 is a diagram illustrating an example of a corrected construction plan database according to the management system.

FIG. 6 is a management flowchart illustrating a management method according to the first embodiment of the present invention.

FIG. 7 is a work image view of the management flow.

FIG. 8 is a configuration block diagram of a management system according to a second embodiment of the present invention.

FIG. 9 is a diagram illustrating an example of a member database according to the management system.

FIG. 10 is a diagram illustrating an example of a construction database according to the management system.

FIG. 11 is a diagram illustrating an example of a corrected construction plan database according to the management system.

FIG. 12 is a management flowchart illustrating a management method according to the second embodiment of the present invention.

FIG. 13 is a configuration block diagram of a management system according to a third embodiment of the present invention.

FIG. 14 is a management flowchart illustrating a management method according to the third embodiment of the present invention.

FIG. 15 is a work image view of the management flow.

FIG. 16 is a configuration block diagram of a management system according to a fourth embodiment of the present invention.

FIG. 17 is a management flowchart illustrating a management method according to the fourth embodiment of the present invention.

FIG. 18 is a configuration block diagram of a management system according to a fifth embodiment of the present invention.

FIG. 19 is a management flowchart illustrating a management method according to the fifth embodiment of the present invention.

FIG. 20 is a work image view of the management flow.

FIG. 21 is a configuration block diagram of a management system according to a sixth embodiment of the present invention.

FIG. 22 is a management flowchart illustrating a management method according to the sixth embodiment of the present invention.

FIG. 23 is a work image view of the management flow.

### DESCRIPTION OF EMBODIMENTS

Next, preferred embodiments of the present invention will be described with reference to the drawings.

### First Embodiment

### (Configuration of Management System According to First Embodiment)

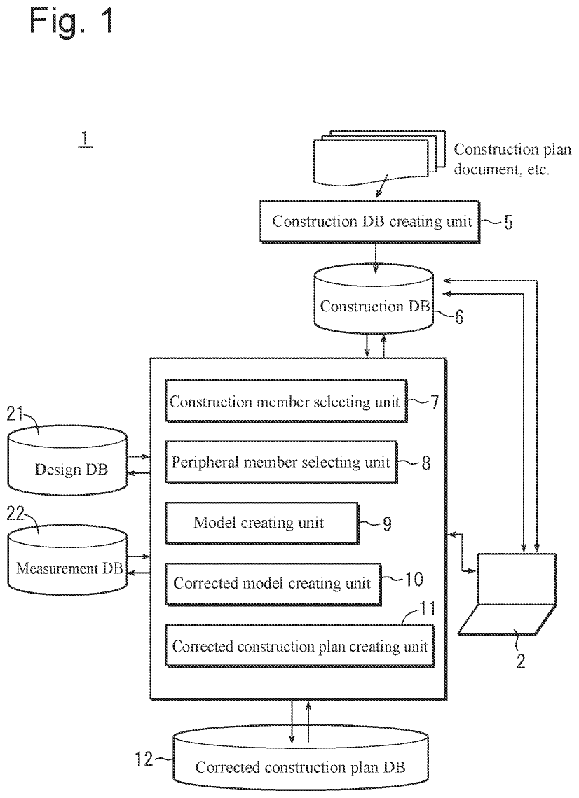

FIG. 1 is a configuration block diagram of a management system 1 according to a first embodiment of the present invention. The management system 1 includes an input/output device 2, a construction database 6, a construction member selecting unit 7, a peripheral member selecting unit 8, a model creating unit 9, a corrected model creating unit 10, a corrected construction plan creating unit 11, and a corrected construction plan database 12, and uses, as data serving as materials, a design database 21 and a measurement database 22.

The input/output device 2 is a general-purpose personal computer, tablet terminal, etc., including at least a computing unit, a storage unit, a communication unit, a display unit, and an operation unit, and can be operated by an administrator.

The respective functional units of the construction member selecting unit 7, the peripheral member selecting unit 8, the model creating unit 9, the corrected model creating unit 10, and the corrected construction plan creating unit 11 are configured by electronic circuits such as a CPU (Central Processing Unit), an ASIC (Application Specific Integrated Circuit), and a PLD (Programmable Logic Device) such as an FPGA (Field Programmable Gate Array). Each functional unit may be configured inside the input/output device 2 or by either separate external hardware/software. In the latter case, each functional unit can transmit and receive information to and from the input/output device 2 through a network.

The construction database 6, the design database 21, the measurement database 22, and the corrected construction plan database 12 are stored in a server computer with which communication can be made through a network. The server computer can communicate with related functional units, and can transmit and receive information.

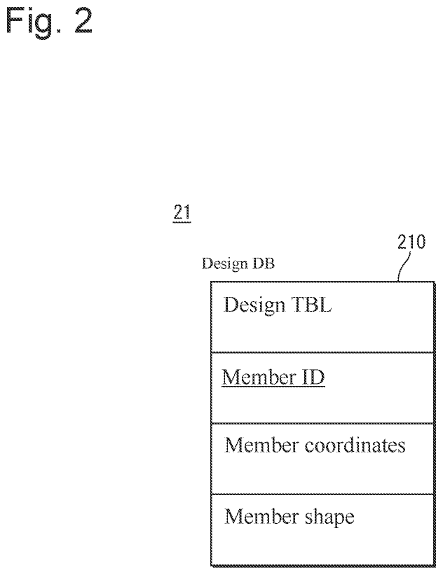

In the design database 21, design data based on design BIM (data on each construction member constituting the construction object in the form of 3D model, the 3D model includes shapes of surfaces, lines, and points) of a construction object as a management object is stored. The design database 21 stores a design table 210 in which, at least, as illustrated in FIG. 2, with respect to each construction member, member identification information (hereinafter, referred to as member ID), member coordinates, and a member shape are associated with each other.

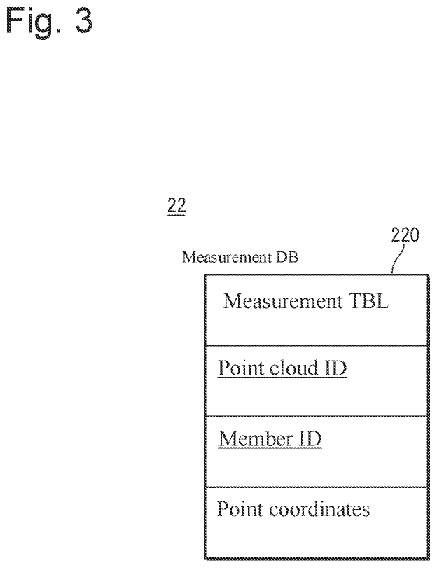

In the measurement database 22, measurement data (point cloud data in which coordinate information is registered, point data, screen data holding coordinate information of measurement spots, and data on construction errors of the construction members) of the construction members described above obtained by using a scanner, etc., are stored. The measurement database 22 stores a measurement table 220 in which, at least, as illustrated in FIG. 3, with respect to each construction member, a point cloud ID, a member ID, and point coordinates are associated with each other.

In the construction database 6, construction data obtained from a construction plan document and two-dimensional construction drawings to be used for construction of the construction object are stored. The construction database 6 includes at least a construction table 610 storing identification information of construction items, a construction member table 611 for managing members related to the construction, and a construction content table 612 for managing construction content.

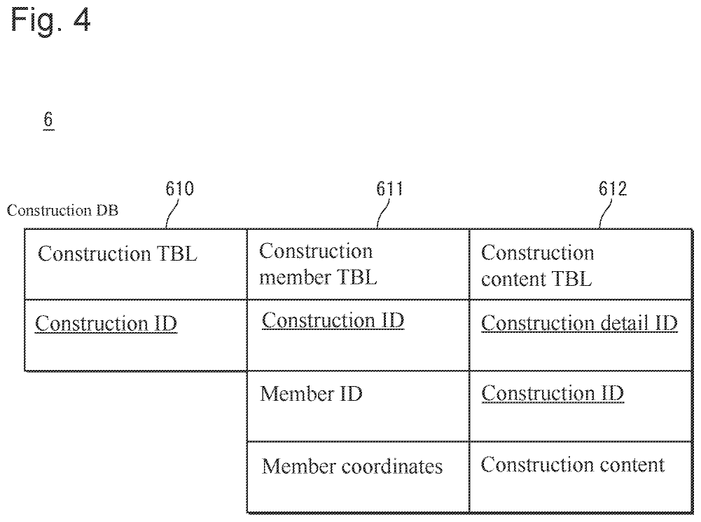

Preferably, as illustrated in FIG. 4, in the construction table 610, identification information (hereinafter, referred to as construction IDs) of the construction items are stored. The construction IDs are, for example, “Iron frame construction,” “Door construction,” and “Sprinkler construction,” etc. In the construction member table 611, construction IDs, member IDs linked to the design database 21 and the measurement database 22, and member coordinates read from two-dimensional construction drawings such as a plan view and an internal finishing table are stored in association with each other. In the construction content table 612, construction IDs, construction detail IDs, and detailed construction content are stored in association with each other. The construction detail IDs are subdivisions of construction content with respect to construction IDs, and are, for example, with respect to “Door construction,” check points such as “Check door open/closed” and “Check correction of member peripheral to door” during and after the construction. Construction content is construction conditions and inspection content obtained from a construction plan document and two-dimensional construction drawings, and is, for example, “ 3/10000 of a floor slope acceptable error reference point with respect to door,” etc.

The construction database 6 may be manually created, or may be created by data analysis by a construction DB creating unit 5. The construction DB creating unit 5 is also configured in the same manner as other functional units, and can transmit and receive information. By scanning two-dimensional construction plan documents and construction drawings, the construction DB creating unit 5 retrieves construction items (construction IDs), members necessary for each construction item, member coordinates of each member, and information on construction conditions and inspection content, and stores these in corresponding portions in the construction table 610, the construction member table 611, and the construction content table 612.

In the corrected construction plan database 12, information on a construction designated member for which a construction plan has been corrected is stored as needed by referring to the construction database 6 and a “design corrected model” described later. The corrected construction plan database 12 includes at least a construction plan table 120 storing identification information of construction plans, a construction designated member table 121 for managing construction designated members for which construction plans have been corrected, and a construction inspection content table 123 for managing construction inspection content related to the construction designated members.

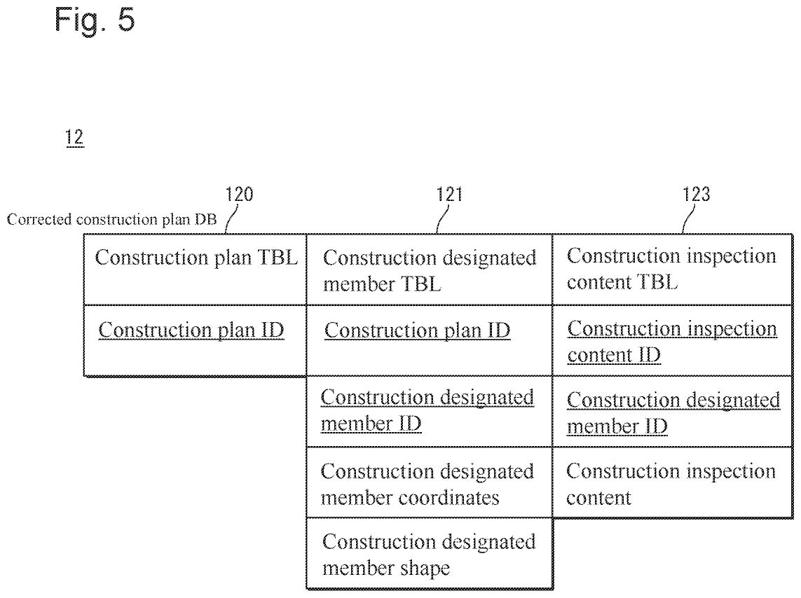

Preferably, as illustrated in FIG. 5, in the construction plan table 120, construction plan IDs are stored. In the construction designated member table 121, construction plan IDs, construction designated member IDs corresponding to member IDs of the construction designated members, construction designated member coordinates, and construction designated member shapes are stored in association with each other. In the construction inspection content table 123, construction inspection content IDs corresponding to construction detail IDs of the construction designated members, construction designated member IDs, and construction inspection content corresponding to the construction content are stored in association with each other. The corrected construction plan database 12 is created by the corrected construction plan creating unit 11. Details of this will be described later.

The construction member selecting unit 7, the peripheral member selecting unit 8, the model creating unit 9, the corrected model creating unit 10, and the corrected construction plan creating unit 11 will be described in a management method according to the present embodiment to be described below.

(Management Method According to First Embodiment)

In a management method according to the present embodiment, by assuming a case where design BIM (design data) is provided for each member of construction management object, data management for creating a design corrected model, a corrected construction plan document, and a corrected construction drawing, is performed.

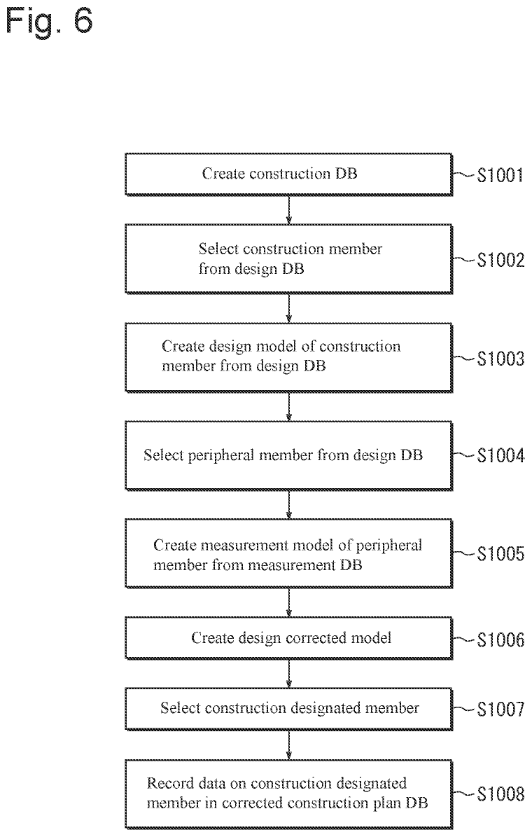

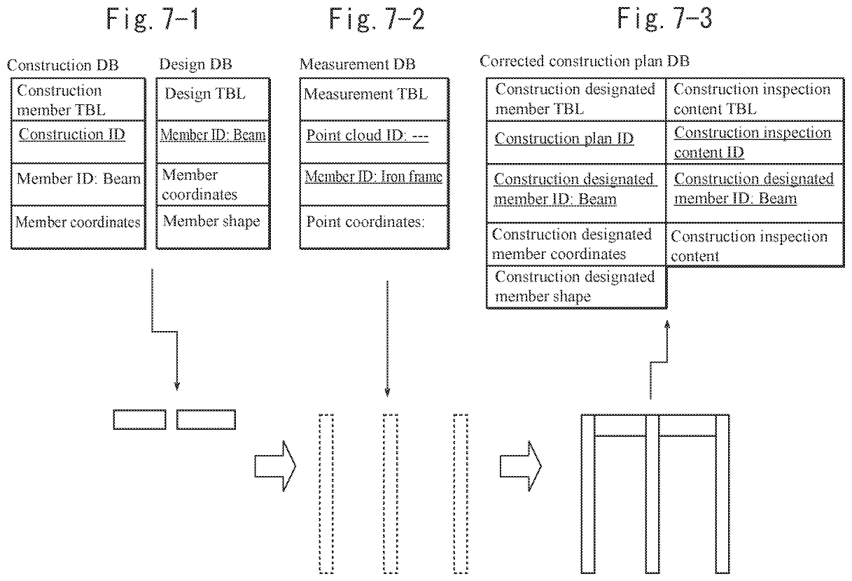

FIG. 6 is a management flowchart illustrating a management method according to the first embodiment of the present invention, and FIG. 7 is a work image view of the management flow.

When management processing is started, in Step S1001, the construction DB creating unit 5 creates a construction database 6. It is also possible that Step S1001 is performed in advance, and management processing is started from the next Step S1002. Step S1002 and subsequent steps are a main part of this management method.

When Step S1002 is started, the construction member selecting unit 7 reads the construction database 6, and displays member IDs on the input/output device 2 and causes an administrator to select a “construction member” as a construction management object. The administrator selects a construction member through the input/output device 2.

Next, the processing shifts to Step S1003, and the model creating unit 9 reads design data linked to the construction member by the member ID from the design database 21, and creates a design model of the construction member.

Next, the processing shifts to Step S1004, and the peripheral member selecting unit 8 reads the design table 210, and extracts a “peripheral member” peripheral to the construction member based on data on coordinates and a shape of the construction member, or displays design models peripheral to the construction member on the input/output device 2 and causes the administrator to select a “peripheral member” peripheral to the construction member.

Next, the processing shifts to Step S1005, and the model creating unit 9 reads measurement data (point cloud data) linked to the peripheral member by the member ID from the measurement database 22, and creates a measurement model of the peripheral member based on the measurement data.

Next, the processing shifts to Step S1006, and the corrected model creating unit 10 creates a “design corrected model” by synthesizing the design model of the construction member created in Step S1003 and the measurement model of the peripheral member created in Step S1005. The design corrected model is created, for example, by correcting, in accordance with a shape (shape in an actual status) of the measurement model, the shape and/or coordinates of the design model so as not to cause interference or correcting the shape and/or coordinates of the design model based on construction error information of the measurement data.

Next, the processing shifts to Step S1007, and the corrected construction plan creating unit 11 causes the administrator to select a member for which a construction plan is desired to be corrected (“construction designated member”) based on the design corrected model through the input/output device 2. As the construction designated member, any one of the construction member and peripheral members may be selected.

After the administrator selects a construction designated member, the processing shifts to Step S1008, and the corrected construction plan creating unit 11 provides a construction designated member ID and a construction plan ID to the construction designated member, and with respect to the construction designated member, set coordinates and a shape of the design corrected model as construction designated member coordinates and a construction designated member shape. Further, by referring to the construction content table 612 in the construction database 6, the corrected construction plan creating unit 11 sets construction content linked by a construction ID of the construction designated member as construction inspection content. According to a selection made by the administrator, the construction designated member coordinates, construction designated member shape, and construction inspection content of the construction designated member are recorded in the corrected construction plan database 12. After recording, this management flow is ended.

In Step S1006, the “design corrected model” may be created by synthesizing the design model, the measurement model, and construction data of the construction member and the peripheral member. In this case, in Step S1008, the corrected construction plan creating unit 11 provides a construction designated member ID and a construction plan ID to the construction designated member, and with respect to the construction designated member, sets coordinates and a shape of the design corrected model as construction designated member coordinates and a construction designated member shape, and sets construction content of the construction designated member as construction inspection content.

Concerning construction data, it is also preferable that processing is performed in which, as construction data to be stored in the corrected construction plan database 12, the administrator arbitrarily selects construction data that the administrator desires to add from the construction database 6 and adds the construction data.

A detailed example will be described with reference to FIG. 7. First, in Step S1002, when a “Beam” is selected as a construction member, a design model of the beam is created in S1003 (reference sign 7-1). Next, in Step S1004, an “Iron frame” that comes into contact with an end portion of the “Beam” is selected as a peripheral member, and in Step S1005, a measurement model of the “Iron frame” is created (reference sign 7-2). Next, in Step S1006, a design corrected model is created by synthesizing the design model of the “Beam” and the measurement model of the “Iron frame” (reference sign 7-3). Next, when the “Beam” is selected as a construction designated member in Step S1007, in Step S1008, construction designated member coordinates, a construction designated member shape, and construction inspection content of the “Beam” based on the design corrected model are recorded in the corrected construction database 12 according to a selection made by the administrator.

As described above, according to the management method and the management system of the present embodiment, in a case where design BIM is provided for each member of construction management object, a design corrected model in which an actual construction status has been reflected is created, and data on design corrected coordinates and shape of the construction designated member are managed together with the construction content. Therefore, a corrected construction plan document and a corrected construction drawing of the construction designated member can be created anytime, and can be turned over to the next construction process (downstream process).

### Second Embodiment

A management system and a management method according to the present embodiment are additionally applied to the first embodiment. The management system and the management method according to the present embodiment are data management preferable in a case where the construction member and/or the peripheral member is movable (moves). The same configuration and process as in the first embodiment are provided with the same reference signs, and descriptions thereof are omitted.

(Configuration of Management System According to Second Embodiment)

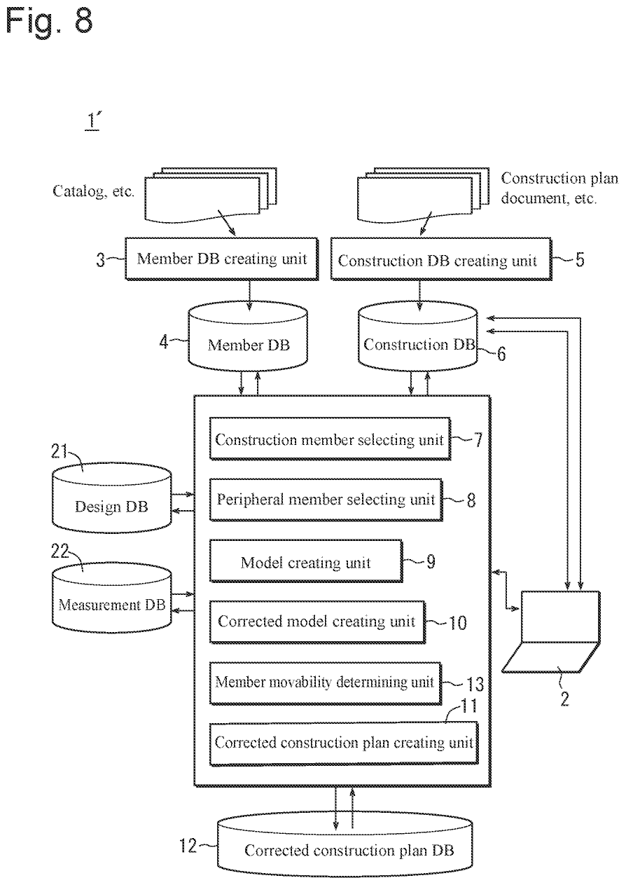

FIG. 8 is a configuration block diagram of a management system 1′ according to a second embodiment of the present invention. The management system 1′ is configured by adding a member database 4 to the first embodiment. The management system 1′ preferably includes a member DB creating unit 3 and a member movability determining unit 13.

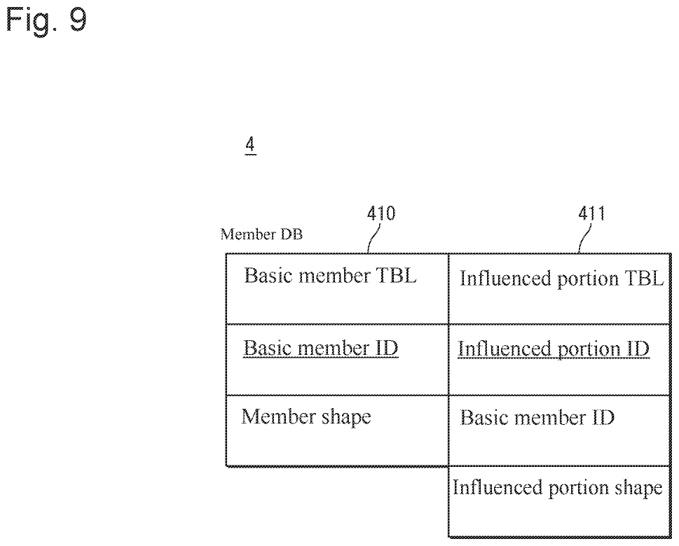

In the member database 4, for each construction member, member basic data (data on member specifications described in a member catalog) is recorded. The member database 4 includes at least a basic member table 410 for managing member shapes of basic members, and an influenced portion table 411 for managing members (or portions) to be influenced by the basic members and shapes of the members (hereinafter, referred to as influenced portion information). Preferably, as illustrated in FIG. 9, in the basic member table 410, identification information of each basic member to be used (hereinafter, referred to as basic member ID) and a member shape of the basic member are stored in association with each other. In the influenced portion table 411, a basic member ID, identification information of a portion to be influenced by the basic member (hereinafter, referred to as influenced portion ID), and information on a shape of the influenced portion are stored in association with each other. For example, with respect to a basic member ID “Steel door,” an influenced portion ID such as “Door bottom surface portion,” and an influenced portion shape such as “Door movable range shape” are stored.

The member database 4 may be manually created, however, preferably created by data analysis by the member DB creating unit 3. The member DB creating unit 3 is also configured in the same manner as other functional units, and can transmit and receive information. The member DB creating unit 3 retrieves information on basic members to be used, member shapes of the basic members, influenced portions to be influenced by the basic members, and shapes of the influenced portions by scanning the catalog, and stores the information in corresponding portions in the basic member table 410 and the influenced portion table 411.

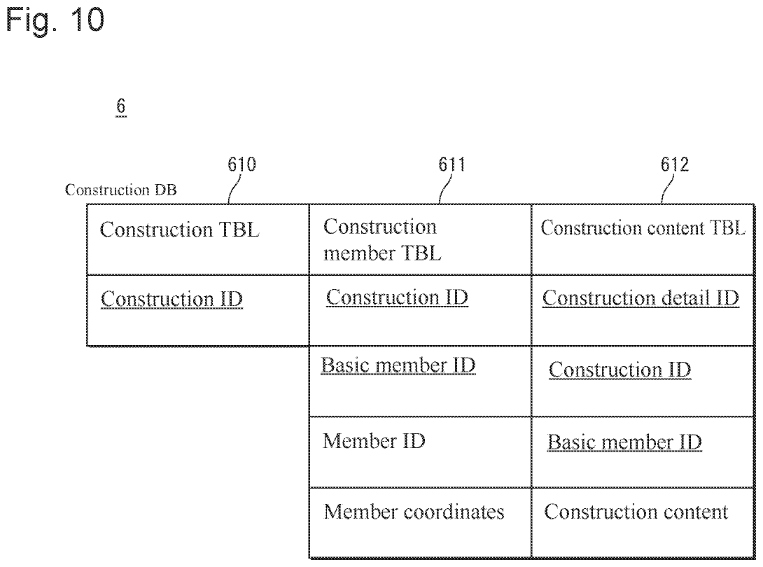

Along with this, as illustrated in FIG. 10, the basic member IDs are also stored in the construction member table 611 and the construction content table 612. The member database 4 is linked to the construction database 6 by the basic member IDs.

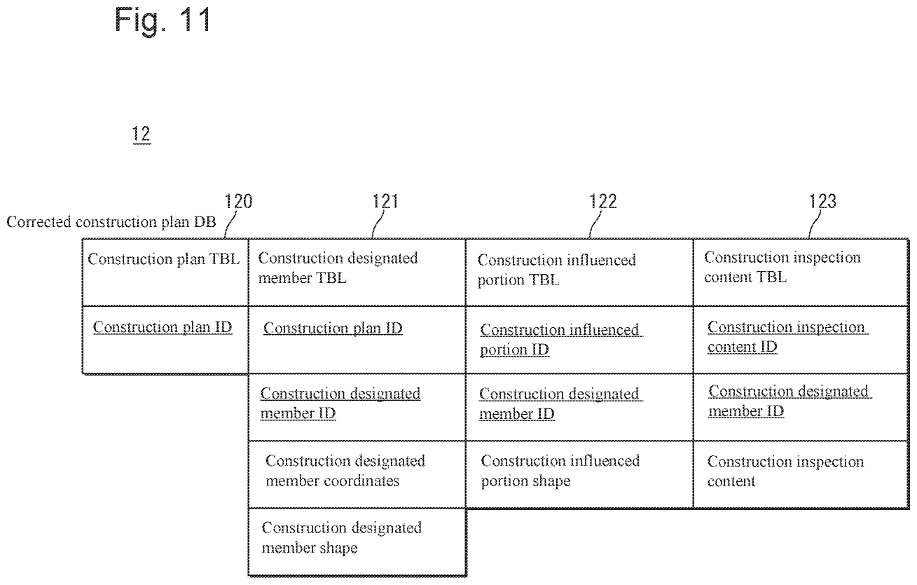

Along with this, as illustrated in FIG. 11, the corrected construction plan database 12 includes a construction influenced portion table 122 for managing an influenced portion of a construction designated member. In the construction influenced portion table 122, a construction influenced portion ID calculated from the basic member table 410, the influenced portion table 411, and the construction member table 611 linked by the basic member ID of the construction designated member, and a construction influenced portion shape corresponding to the influenced portion shape of the construction designated member are stored in association with a construction designated member ID. For example, with respect to a construction designated member “Steel door,” information in the basic member table 410, the influenced portion table 411, and the construction member table 611, are acquired, a construction influenced portion ID “Floor” is calculated from coordinates of a bottom surface portion of the door, and a “Door's movable range shape” is acquired as a construction influenced portion shape.

(Management Method According to Second Embodiment)

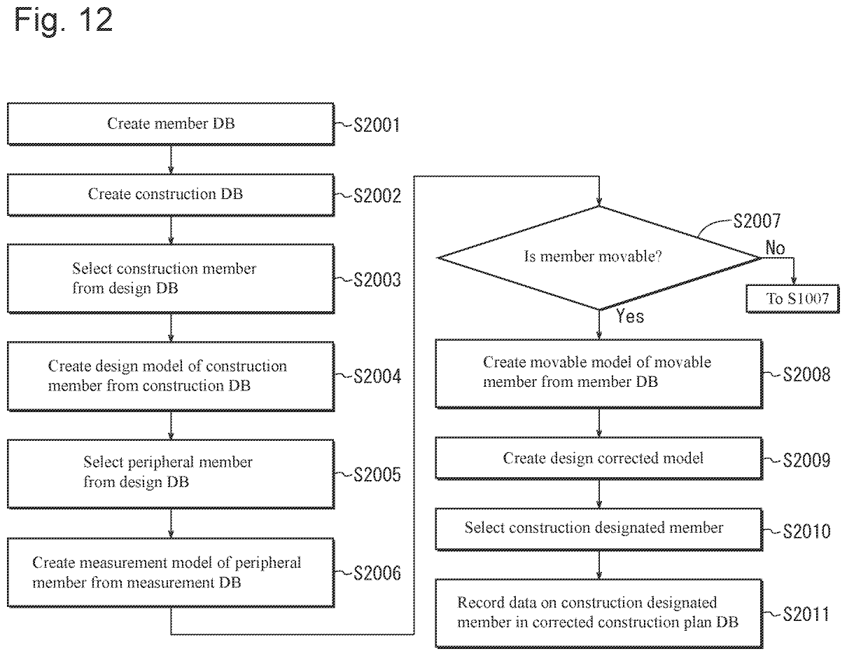

FIG. 12 is a management flowchart illustrating a management method according to the second embodiment of the present invention.

When management processing is started, the member DB creating unit 3 creates the member database 4 in Step S2001, and the construction DB creating unit 5 creates the construction database 6 in Step S2002. It is also possible that Steps S2001 and S2002 are performed in advance, and the management processing is started from the next Step S2003. Step S2003 and subsequent steps are a main part of this management method.

Steps S2003 to S2006 are the same as Steps S1002 to S1005. That is, a construction member is selected based on the construction database 6 in Step S2003, a design model of the construction member is created based on the design database 21 in Step S2004, a peripheral member is selected based on the design database 21 in Step S2005, and a measurement model of the peripheral member is created based on the measurement database 22 in Step S2006.

Next, the processing shifts to Step S2007, and the member movability determining unit 13 or an administrator refers to the member database 4 for the construction member and the peripheral member, and determines whether there is an influenced portion. When an influenced portion ID is found, the member is determined to be “movable” and the processing shifts to Step S2008. When no influenced portion ID is found, the member is determined to be “unmovable,” and a design corrected model is created in Step S1007.

On the other hand, when the processing shifts to Step S2008, the member movability determining unit 13 or the administrator refers to the member database 4 for the “movable member” determined to be movable, and inputs an influenced portion shape as movability information of the member into the model creating unit 9. The model creating unit 9 creates a movable model of the movable member (the construction member and/or the peripheral member) based on the movability information. The movable model is created by providing information on a movable range to the design model or the measurement model of the movable member.

Next, the processing shifts to Step S2009, and when the construction member is a movable member, the corrected model creating unit 10 creates a “design corrected model” by synthesizing the measurement model of the peripheral member created in Step S2006 and the movable model of the construction member created in Step S2008. When the peripheral member is a movable member, a “design corrected model” is created by synthesizing the design model of the construction member created in Step S2004 and the movable model of the peripheral member created in Step S2007.

Next, the processing shifts to Step S2010, and the corrected construction plan creating unit 11 causes the administrator to select a member for which a construction plan is desired to be corrected (“correction designated member”) based on the design corrected model through the input/output device 2 in the same manner as in Step S1007.

Next, the processing shifts to Step S2011, and in the same manner as in Step S1008, the corrected construction plan creating unit 11 provides a construction designated member ID and a construction plan ID to the construction designated member, and with respect to the construction designated member, sets coordinates and a shape of the design corrected model as construction designated member coordinates and a construction designated member shape. Further, the corrected construction plan creating unit 11 sets construction content related to the construction designated member as construction inspection content by referring to construction database 6, and sets influenced portion information related to the construction designated member as construction influenced portion information by referring to the member database 4, and according to a selection made by the administrator, records the construction designated member coordinates, the construction designated member shape, the construction inspection content, and the construction influenced portion information in the corrected construction plan database 12. After recording, this management flow is ended.

As described above, according to the management method and the management system of the present embodiment, in a case where the construction designated member is movable, data on a member or portion to be influenced by the movement is also managed, so that a corrected construction plan document and a corrected construction drawing including influences from the movement can be created anytime, and can be turned over to the next construction process (downstream process).

### Third Embodiment

In a management system and a management method according to the present embodiment, by assuming a case where a or some member of a construction management object is not managed by design BIM (but included in a construction drawing), data management for creating a design corrected model, a corrected construction plan document, and a corrected construction drawing is performed. The same configuration and process as in the embodiments described above are provided with the same reference signs, and descriptions thereof are omitted.

(Configuration of Management System According to Third Embodiment)

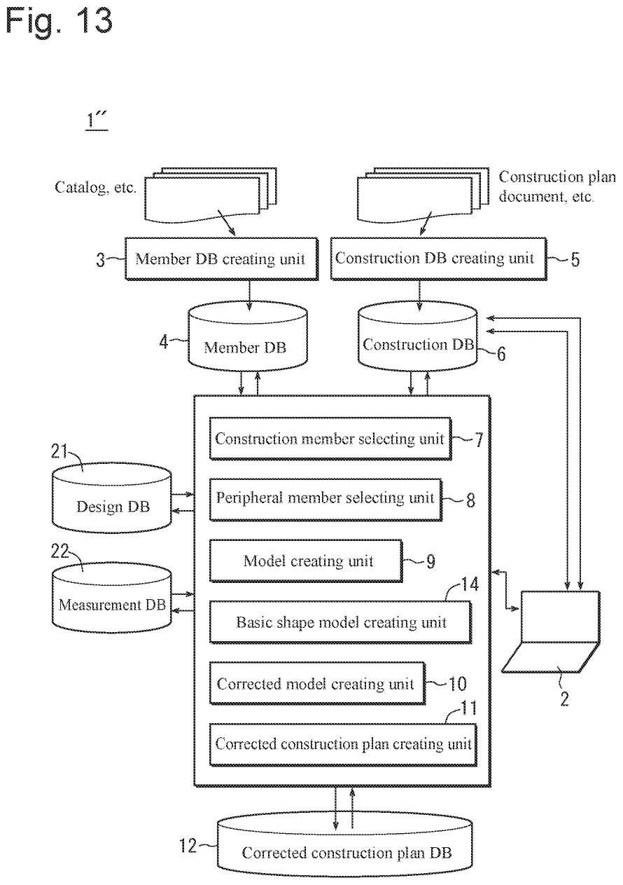

FIG. 13 is a configuration block diagram of a management system 1″ according to a third embodiment of the present invention. The management system 1″ includes the input/output device 2, the member database 4, the construction database 6, the construction member selecting unit 7, the peripheral member selecting unit 8, the model creating unit 9, a basic shape model creating unit 14, the corrected model creating unit 10, the corrected construction plan creating unit 11, and the corrected construction plan database 12, and uses, as data serving as materials, the design database 21 and the measurement database 22. The member database 4 is preferably created by the member DB creating unit 3, the construction database 6 is preferably created by the construction DB creating unit 5, and the corrected construction plan database 12 is created by the corrected construction plan creating unit 11.

The construction member selecting unit 7, the peripheral member selecting unit 8, the model creating unit 9, the basic shape model creating unit 14, the corrected model creating unit 10, and the corrected construction plan creating unit 11 in the present embodiment will be described in a management method according to the present embodiment to be described below.

(Management Method According to Third Embodiment)

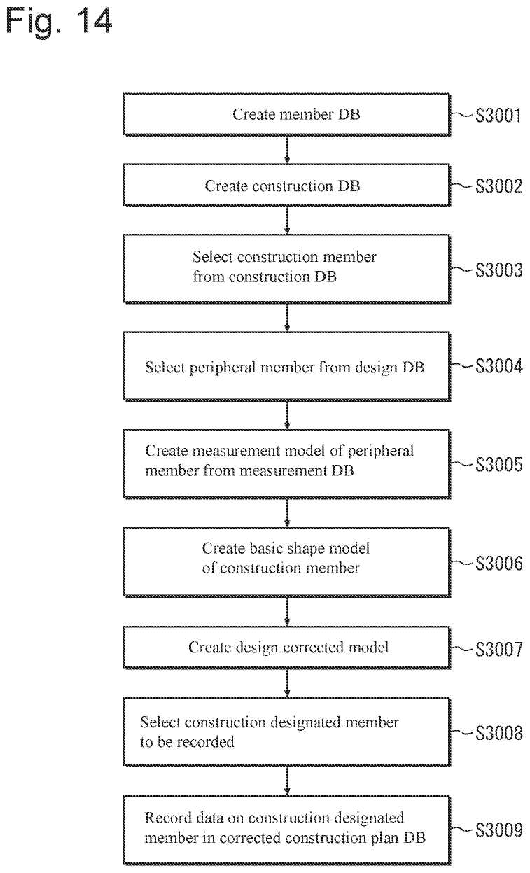

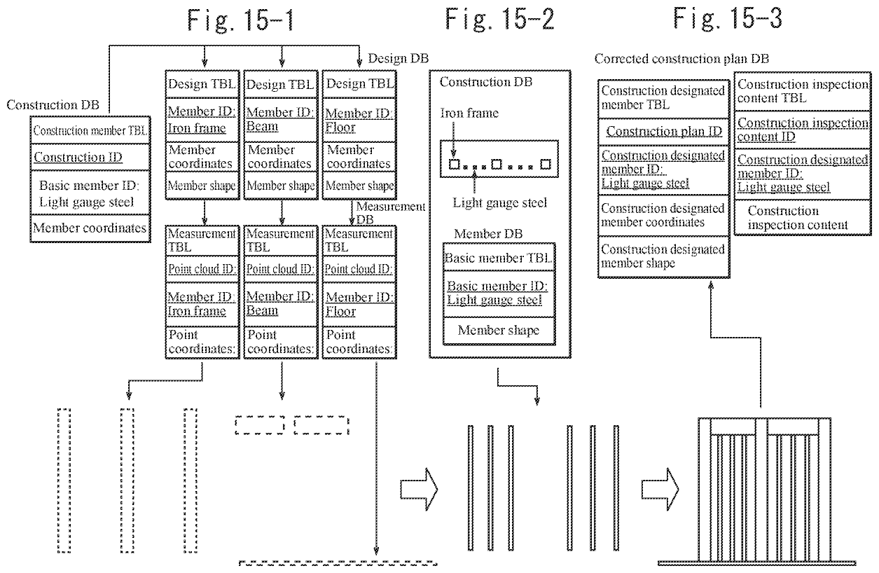

FIG. 14 is a management flowchart illustrating a management method according to the third embodiment of the present invention, and FIG. 15 is a work image view of the management flow.

When management processing is started, the member DB creating unit 3 creates the member database 4 in Step S3001, and the construction DB creating unit 5 creates the construction database 6 in Step S3002. It is also possible that Steps S3001 and S3002 are performed in advance, and the management processing is started from the next Step S3003. Step S3003 and subsequent steps are a main part of this management method.

When the processing shifts to Step S3003, the construction member selecting unit 7 reads the construction member table 611 (FIG. 10) in the construction database 6 and causes an administrator to select a “construction member” of a construction management object.

Next, the processing shifts to Step S3004, and the peripheral member selecting unit 8 reads the design table 210 in the design database 21, and extracts a “peripheral member” peripheral to the construction member based on member coordinates (coordinates of an end portion, etc.,) of the construction member referred to from the construction member table 611, or displays design models peripheral to the construction member on the input/output device 2 and causes the administrator to select a “peripheral member” peripheral to the construction member.

Next, the processing shifts to Step S3005, and with respect to the peripheral member, the model creating unit 9 reads measurement data (point cloud data) linked by the member ID from the measurement database 22 (FIG. 3), and creates a measurement model of the construction member based on the measurement data.

Next, the processing shifts to Step S3006, and with respect to the construction member, the basic shape model creating unit 14 reads member basic data (member shape) of the construction member from the member database 4 (FIG. 9) and construction data (member coordinates) in the construction database 6 based on the basic member ID, and creates a basic shape model of the construction member based on the member basic data and the construction data.

Next, the processing shifts to Step S3007, and the corrected model creating unit 10 creates a “design corrected model” by synthesizing the measurement model of the peripheral member created in Step S3005 with the basic shape model of the construction member created in Step S3006. The design corrected model is created, for example, by correcting, in accordance with a shape of the measurement model (shape in an actual status), a shape and/or coordinates of the basic shape model so as not to cause interference or correcting a shape and/or coordinates of the basic shape model based on construction error information.

Next, the processing shifts to Step S3008, and the corrected construction plan creating unit 11 causes the administrator to select a member for which a construction plan is desired to be corrected (“construction designated member”) based on the design corrected model through the input/output device 2 in the same manner as in Step S1007. As the construction designated member, any one of the construction member and peripheral members may be selected.

Next, the processing shifts to Step S3009, and with respect to the construction designated member, the corrected construction plan creating unit 11 sets coordinates and a shape of the design corrected model as construction designated member coordinates and a construction designated member shape as in Step S1008. Further, the corrected construction plan creating unit 11 sets construction content related to the construction designated member as construction inspection content by referring to the construction database 6. Then, according to a selection made by the administrator, the construction designated member coordinates, the construction designated member shape, and the construction inspection content of the construction designated member are recorded in the corrected construction plan database 12. After recording, this management flow is ended.

It is also preferable that, in Step S3007, the “design corrected model” is created by synthesizing the measurement model, the basic shape model, and construction data of the construction member and the peripheral member.

Concerning creation and recording of the basic shape model, it is also preferable that according to a request of the administrator, processing is performed in which only the basic shape model of the construction member is created, and the construction member is directly recorded as a construction designated member in the corrected construction plan database 12. That is, a management system and a management method only configured by Step S3003 to be performed by the construction member selecting unit 7, Step S3006 to be performed by the basic shape model creating unit 14, and Step S3009 to be performed by the corrected construction plan creating unit 11 are also preferable.

Concerning construction data, it is also preferable that processing is performed in which, as construction data to be stored in the corrected construction plan database 12, construction data desired to be added is directly selected from the construction database 6 and added by the administrator.

A detailed example will be described with reference to FIG. 15. First, when a “Light gauge steel” is selected as a construction member through Step S3003, a “Beam,” a “Floor,” and an “Iron frame” peripheral to the “Light gauge steel” are selected as peripheral members in Step S3004. Next, measurement models of the “Beam,” the “Floor,” and the “Iron frame” as peripheral members are created in Step S3005 (reference sign 15-1), and a basic shape model of the “Light gauge steel” as the construction member is created in Step S3006 (reference sign 15-2). Next, a design corrected model is created by synthesizing the measurement models of the “Beam,” “Floor,” and “Iron frame” with the basic shape model of the “Light gauge steel” in Step S3007 (reference sign 15-3). Next, when the “Light gauge steel” is selected as a construction designated member in Step S3008, construction designated member coordinates, a construction designated member shape, and construction inspection content of the “Light gauge steel” based on the design corrected model are recorded in the corrected construction database 12 in Step S3009 according to a selection made by the administrator.

As described above, according to the management method and the management system of the present embodiment, in the case where a member of a construction management object is not managed by design BIM, the data on this member (construction member) is complemented by setting as a construction designated member, and design correction data (coordinates, shape) is recorded together with construction content in the corrected construction plan database 12. Therefore, with respect to a member not managed by design BIM, a design corrected model, a corrected construction plan document, and a corrected construction drawing can be created anytime, and can be turned over to the next construction process (downstream process).

### Fourth Embodiment

A management system and a management method according to the present embodiment are additionally applied to the third embodiment. The management system and the management method according to the present embodiment are data management preferable in a case where the construction member or the peripheral member is movable (moves). The same configuration and process as in the third embodiment are provided with the same reference signs, and descriptions thereof are omitted.

(Configuration of Management System According to Fourth Embodiment)

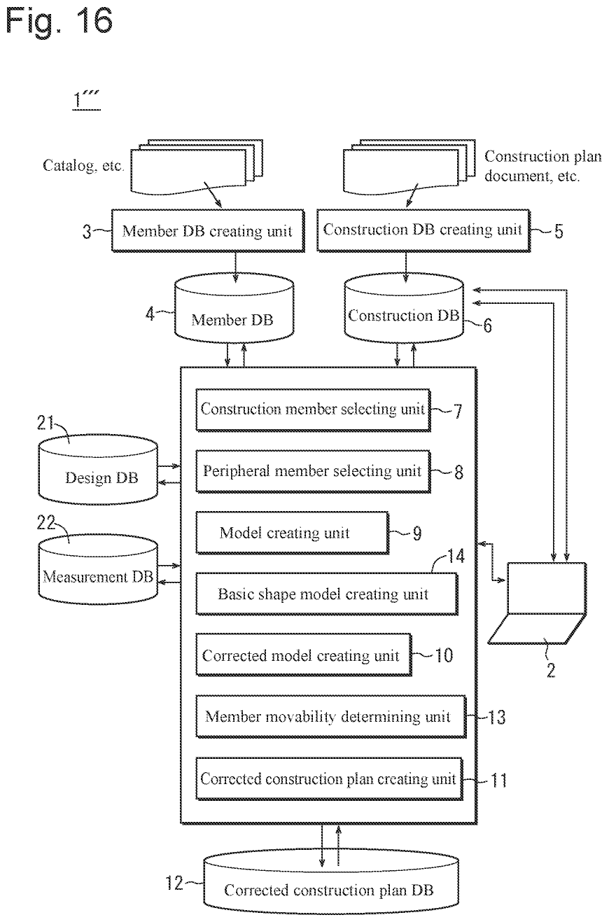

FIG. 16 is a configuration block diagram of a management system 1′″ according to a fourth embodiment of the present invention. The management system 1′″ preferably includes the member movability determining unit 13 in the third embodiment.

(Management Method According to Fourth Embodiment)

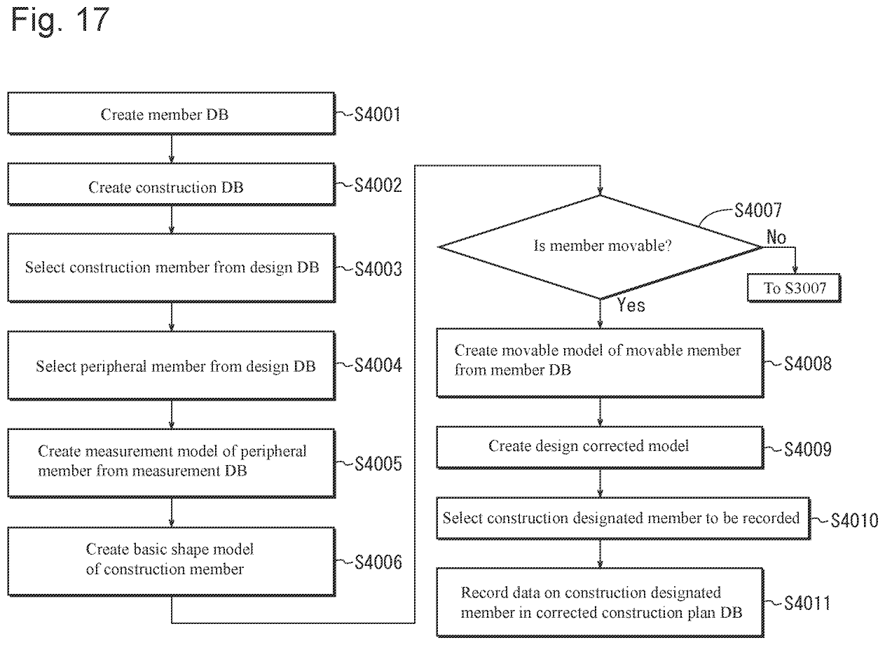

FIG. 17 is a management flowchart illustrating a management method according to the fourth embodiment of the present invention.

When management processing is started, the member DB creating unit 3 creates the member database 4 in Step S4001, and the construction DB creating unit 5 creates the construction database 6 in Step S4002. It is also possible that these steps are performed in advance, and the processing is started from Step S4003. Step S4003 and subsequent steps are a main part of this management method.

Steps S4003 to S4006 are the same as Steps S3003 to S3006. That is, a construction member is selected in Step S4003, a peripheral member is selected in Step S4004, a measurement model of the peripheral member is created in Step S4005, and a basic shape model of the construction member is created in Step S4006.

Next, the processing shifts to Step S4007, and the member movability determining unit 13 or the administrator refers to the member database 4 for the construction member and the peripheral member and determines whether there is an influenced portion. When an influenced portion ID is found, the member is determined to be “movable” and the processing shifts to Step S4008. When no influenced portion ID is found, the member is determined to be “unmovable,” and a design corrected model is created in Step S3007.

On the other hand, when the processing shifts to Step S4008, the member movability determining unit 13 or the administrator refers to the member database 4 for the “movable member” determined to be movable, and inputs an influenced portion shape as movability information of the member into the model creating unit 9. The model creating unit 9 creates a movable model of the movable member (construction member and/or peripheral member) based on the movability information. The movable model is created by providing information on a movable range to the measurement model or the basic shape model of the movable member.

Next, the processing shifts to Step S4009, and when the construction member is a movable member, the corrected model creating unit 10 creates a “design corrected model” by synthesizing the movable model of the construction member created in Step S4008 and the measurement model of the peripheral member created in Step S4006. When the peripheral member is a movable member, a “design corrected model” is created by synthesizing the basic shape model of the construction member created in Step S4006 and the movable model of the peripheral member created in Step S4008.

Next, the processing shifts to Step S4010, and the corrected construction plan creating unit 11 causes the administrator to select a member for which a construction plan is desired to be corrected (“construction designated member”) based on the design corrected model through the input/output device 2 in the same manner as in Step S3008.

Next, the processing shifts to Step S4011, and as in Step S3009, the corrected construction plan creating unit 11 provides a construction designated member ID and a construction plan ID to the construction designated member, and with respect to the construction designated member, sets coordinates and a shape of the design corrected model as construction designated member coordinates and a construction designated member shape. Further, the corrected construction plan creating unit 11 sets construction content related to the construction designated member as construction inspection content by referring to the construction database 6, sets influenced portion information related to the construction designated member as construction influenced portion information by referring to the member database 4, and according to a selection made by the administrator, records the construction designated member coordinates, the construction designated member shape, the construction inspection content, and the construction influenced portion information in the corrected construction plan database 12. After recording, this management flow is ended.

As described above, according to the management method and the management system of the present embodiment, in a case where the construction designated member is movable, data on a member or portion to be influenced by the movement is also managed, so that a corrected construction plan document and a corrected construction drawing including influences from the movement can be created anytime, and can be turned over to the next construction process (downstream process).

### Fifth Embodiment

In a management system and a management method according to the present embodiment, by utilizing data managed in the corrected construction plan database 12, data management to reflect the correction in design BIM (upstream) is performed. The present embodiment is management when a correction reflection member is included in design BIM (design data).

(Configuration of Management System According to Fifth Embodiment)

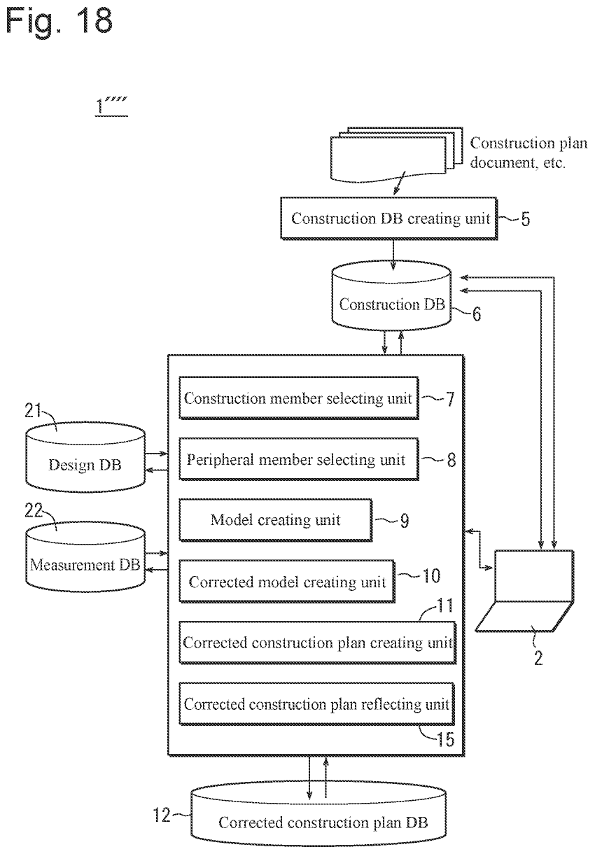

FIG. 18 is a configuration block diagram of a management system 1″″ according to a fifth embodiment of the present invention. The management system 1″″ of the present embodiment is configured by adding a corrected construction plan reflecting unit 15 to the first embodiment. The corrected construction plan reflecting unit 15 is also configured in the same manner as other functional units, and can transmit and receive information.

(Management Method According to Fifth Embodiment)

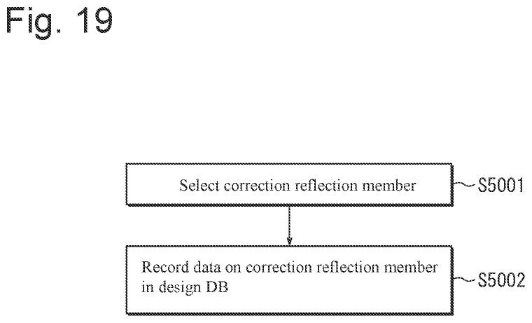

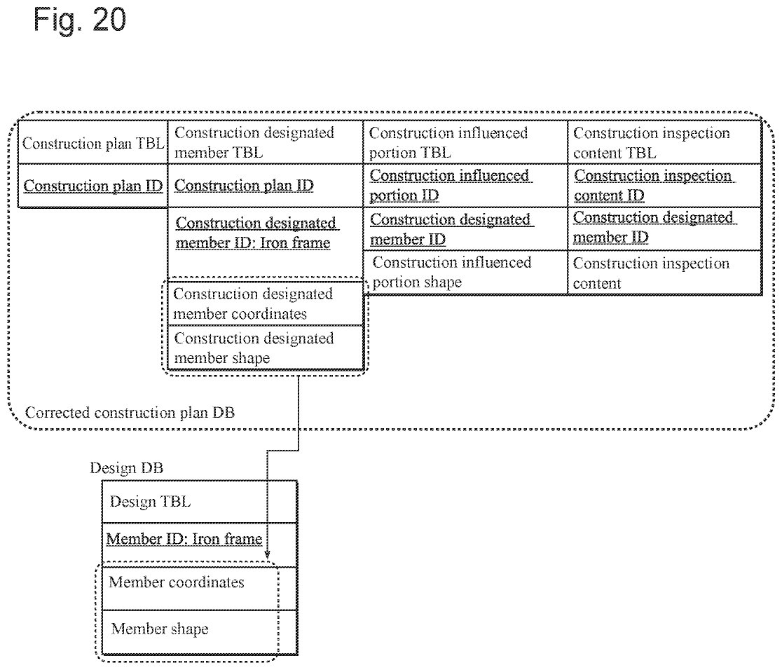

FIG. 19 is a management flowchart illustrating a management method according to the fifth embodiment of the present invention, and FIG. 20 is a work image view of the management flow. Upon starting of management processing according to the present embodiment, the processing shifts to Step S5001, and the corrected construction plan reflecting unit 15 reads the corrected construction plan database 12 and causes an administrator to select a “correction reflection member” the correction of which is desired to be reflected in design BIM based on a construction designated member ID.

Next, the processing shifts to Step S5002, and the corrected construction plan reflecting unit 15 writes data on construction designated member coordinates and a construction designated member shape of the correction reflection member over member coordinates and a member shape linked by the member ID of the correction reflection member in the design database 21 (refer to FIG. 20). After updating the design database 21, the corrected construction plan reflecting unit 15 ends this management flow.

### Sixth Embodiment

In a management system and a management method according to the present embodiment, by utilizing data managed in the corrected construction plan database 12, data management to reflect correction in design BIM (upstream) is performed. The present embodiment is management when a correction reflection member is not included in design BIM (design data).

(Configuration of Management System According to Sixth Embodiment)

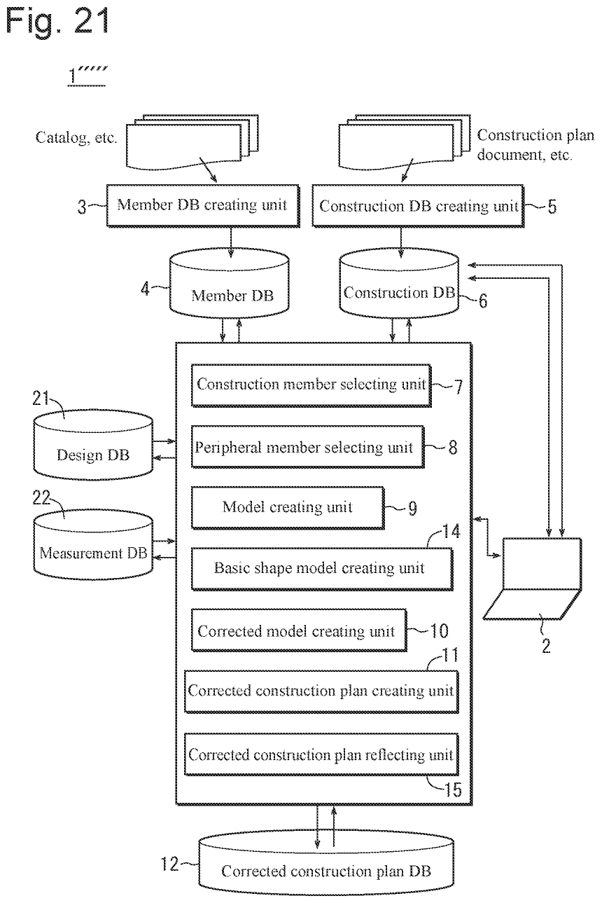

FIG. 21 is a configuration block diagram of a management system 1′″″ according to a sixth embodiment of the present invention. The management system 1′″″ of the present embodiment is configured by adding the corrected construction plan reflecting unit 15 to the third embodiment.

(Management Method According to Sixth Embodiment)

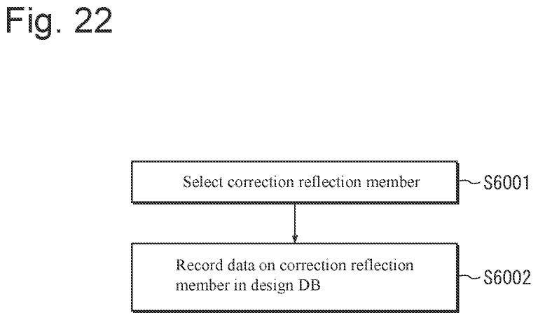

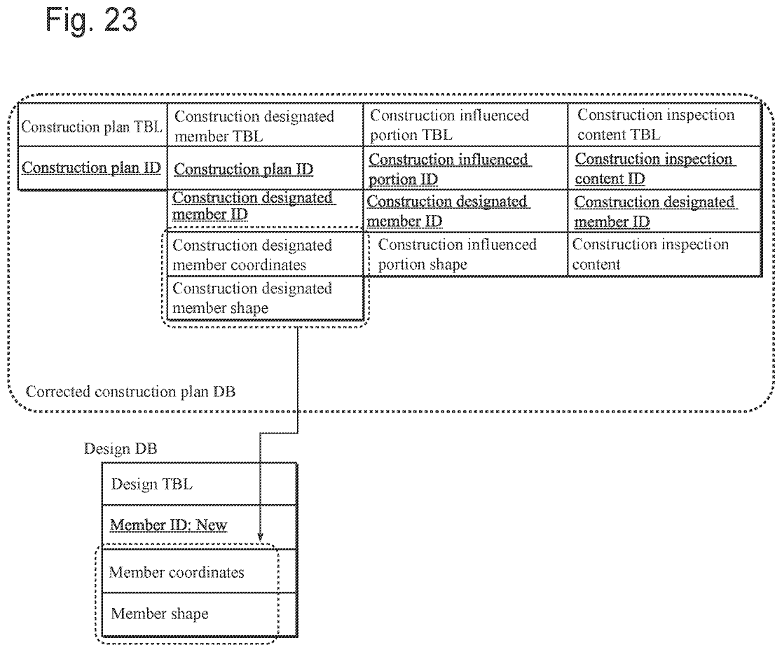

FIG. 22 is a management flowchart illustrating a management method according to the sixth embodiment of the present invention, and FIG. 23 is a work image view of the management flow. Upon starting of management processing according to the present embodiment, the processing shifts to Step S6001, and the corrected construction plan reflecting unit 15 reads the corrected construction plan database 12 and causes an administrator to select a “correction reflection member” based on a construction designated member ID.

Next, the processing shifts to Step S6002, and the corrected construction plan reflecting unit 15 provides a new member ID to data on construction designated member coordinates and a construction designated member shape of the selected correction reflection member, and adds the data into the design database 21 (refer to FIG. 23). After updating the design database 21, the corrected construction plan reflecting unit 15 ends this management flow.

As described above, according to the management methods and the management systems of the fifth and sixth embodiments, design correction data of a member managed in the corrected construction plan database 12 in which an actual construction status has been reflected can be reflected in or added to design BIM (upstream process). Therefore, at a construction site, a situation where information of design BIM to be referred to each time of the progression of processes is used while being left old in a downstream process, and an actual on-site status and the construction drawing do not match, can be prevented, and it becomes possible to efficiently utilize BIM at the construction site. The corrected construction plan reflecting unit 15 in the present embodiment is also applicable to the second and fourth embodiments.

The data recorded in the corrected construction plan database 12 in the first to sixth embodiments can be output from the corrected construction plan database 12 to an external system, and the design correction data can be used and utilized in the external system.

Preferred embodiments and modifications of the present invention have been described above, and each embodiment and each modification can be combined based on the knowledge of a person skilled in the art, and such a combined embodiment is also included in the scope of the present invention.

### REFERENCE SIGNS LIST

1, 1′, 1″, 1′″, 1″″, 1′″″ Management system
2 Input/output device
4 Member database
410 Basic member table
411 Influenced portion table
6 Construction database
610 Construction table
611 Construction member table
612 Construction content table
7 Construction member selecting unit
8 Peripheral member extracting unit
9 Model creating unit
10 Corrected model creating unit
11 Corrected construction plan creating unit
12 Corrected construction plan database
120 Construction plan table
121 Construction designated member table
122 Construction influenced portion table
123 Construction inspection content table
13 Member movability determining unit
14 Basic shape model creating unit
15 Corrected construction plan reflecting unit
21 Design database
22 Measurement database

1. A management method comprising: by transmitting and receiving information to and from a design database recording design data of construction members constituting a construction object, a measurement database recording measurement data of the construction members, and a construction database storing construction data of the construction members,
a step (A) of selecting a construction member from the construction database;
a step (B) of creating a design model of the construction member from design data of the construction member in the design database;
a step (C) of selecting a peripheral member peripheral to the construction member from the design database;
a step (D) of creating a measurement model of the peripheral member from measurement data of the peripheral member in the measurement database;
a step (E) of creating a design corrected model by synthesizing the design model and the measurement model;
a step (F) of selecting a construction designated member for which a construction plan is corrected based on the design corrected model; and
a step (G) of recording, with respect to the construction designated member, coordinates and a shape of the design corrected model as construction designated member coordinates and a construction designated member shape, and construction content of the construction designated member as construction inspection content, in a corrected construction plan database.

2. The management method according to claim 1, wherein further,
by transmitting and receiving information to and from a member database recording member basic data of the construction members,
before the step (E), whether the construction member and the peripheral member are movable members is determined by referring to the member database, and when the member is determined to be unmovable, the design corrected model is created in the step (E), and when the member is determined to be movable, movability information of the movable member is read from the member database and a movable model of the movable member is created, and a design corrected model is created by synthesizing the design model or the measurement model with the movable model, and the processing shifts to the step (F), and
in the step (G), by further referring to the member database, construction influenced portion information based on the movability information of the movable member is recorded in the corrected construction plan database.

3. A management method comprising: by transmitting and receiving information to and from a design database recording design data of construction members constituting a construction object, a measurement database recording measurement data of the construction members, a member database recording member basic data of the construction members, and a construction database storing construction data of the construction members,
a step (L) of selecting a construction member from the construction database;
a step (M) of selecting a peripheral member peripheral to the construction member from the design database;
a step (N) of creating a measurement model of the peripheral member based on measurement data in the measurement database;
a step (O) of creating a basic shape model of the construction member from the member basic data in the member database and the construction data in the construction database;
a step (P) of creating a design corrected model by synthesizing the measurement model and the basic shape model;
a step (Q) of selecting a construction designated member for which a construction plan is corrected based on the design corrected model; and
a step (R) of recording, with respect to the construction designated member, coordinates and a shape of the design corrected model as construction designated member coordinates and a construction designated member shape, and construction content of the construction designated member as construction inspection content, in a corrected construction plan database.

4. The management method according to claim 3, wherein, further,
before the step (P), whether the construction member and the peripheral member are movable members is determined by referring to the member database, and when the member is determined to be unmovable, the design corrected model is created in the step (P), and when the member is determined to be movable, movability information of the movable member is read from the member database, a movable model of the movable member is created, a design corrected model is created by synthesizing the measurement model, the basic shape model, and the movable model, and the processing shifts to the step (Q), and
in the Step (R), by further referring to the member database, influenced portion information based on the movability information of the movable member is recorded in the corrected construction plan database.

5. The management method according to claim 1, further comprising:
a step of writing the construction designated member coordinates and the construction designated member shape of the construction designated member recorded in the corrected construction plan database over member coordinates and a member shape linked by member identification information of the construction designated member in the design database.

6. The management method according to claim 3, further comprising: a step of newly adding the construction designated member, the construction designated member coordinates, and the construction designated member shape recorded in the corrected construction plan database into the design database.

7. A storage medium storing a management program describing the management method according to claim 1.

8. A management system comprising:
a design database recording design data of construction members constituting a construction object;
a measurement database recording measurement data of the construction members;
a construction database storing construction data of the construction members;
a construction member selecting unit configured to select a construction member from the construction database;
a peripheral member selecting unit configured to select a peripheral member peripheral to the construction member from the design database;
a model creating unit configured to create a design model of the construction member from the design data of the construction member, and a measurement model of the peripheral member from the measurement data of the peripheral member;
a corrected model creating unit configured to create a design corrected model by synthesizing the design model and the measurement model; and
a corrected construction plan creating unit configured to select a construction designated member for which a construction plan is corrected based on the design corrected model, and record, with respect to the construction designated member, coordinates and a shape of the design corrected model as construction designated member coordinates and a construction designated member shape, and construction content of the construction designated member as construction inspection content, in a corrected construction plan database.

9. The management system according to claim 8, further comprising:
a member database recording member basic data of the construction members; and
a member movability determining unit configured to determine whether the construction member and the peripheral member are movable members by referring to the member database, and when determining that the member is movable, read movability information of the movable member from the member database and create a movable model of the movable member, wherein
the corrected model creating unit creates a design corrected model by synthesizing the design model or the measurement model with the movable model, and
the corrected construction plan creating unit refers to the member database and further records construction influenced portion information based on the movability information of the movable member in the corrected construction plan database.

10. A management system comprising:
a design database recording design data of construction members constituting a construction object;
a measurement database recording measurement data of the construction members;
a member database recording member basic data of the construction members;
a construction database storing construction data of the construction members;
a construction member selecting unit configured to select a construction member from the construction database;
a peripheral member selecting unit configured to select a peripheral member peripheral to the construction member from the design database;
a model creating unit configured to create a measurement model of the peripheral member based on the measurement data in the measurement database;
a basic shape model creating unit configured to create a basic shape model of the construction member from the member basic data in the member database and the construction data in the construction database;
a corrected model creating unit configured to create a design corrected model by synthesizing the measurement model and the basic shape model; and
a corrected construction plan creating unit configured to select a construction designated member for which a construction plan is corrected based on the design corrected model, and record, with respect to the construction designated member, coordinates and a shape of the design corrected model as construction designated member coordinates and a construction designated member shape, and construction content of the construction designated member as construction inspection content, in a corrected construction plan database.

11. The management system according to claim 10, further comprising:
a member movability determining unit configured to determine whether the construction member and the peripheral member are movable members by referring to the member database, and when determining that the member is movable, read movability information of the movable member from the member database and create a movable model of the movable member, wherein
the corrected model creating unit creates a design corrected model by synthesizing the measurement model, the basic shape model, and the movable model, and
the corrected construction plan creating unit refers to the member database and further records construction influenced portion information based on the movability information of the movable member in the corrected construction plan database.

12. The management system according to claim 8 or 9, further comprising:
a corrected construction plan reflecting unit configured to write the construction designated member coordinates and the construction designated member shape of the construction designated member recorded in the corrected construction plan database over member coordinates and a member shape linked by member identification information of the construction designated member in the design database.

13. The management system according to claim 10, further comprising: a corrected construction plan reflecting unit configured to newly add the construction designated member, the construction designated member coordinates, and the construction designated member shape recorded in the corrected construction plan database into the design database.

14. The management method according to claim 2, further comprising:
a step of writing the construction designated member coordinates and the construction designated member shape of the construction designated member recorded in the corrected construction plan database over member coordinates and a member shape linked by member identification information of the construction designated member in the design database.

15. The management method according to claim 4, further comprising: a step of newly adding the construction designated member, the construction designated member coordinates, and the construction designated member shape recorded in the corrected construction plan database into the design database.

16. A storage medium storing a management program describing the management method according to claim 3.

17. The management system according to claim 9, further comprising:
a corrected construction plan reflecting unit configured to write the construction designated member coordinates and the construction designated member shape of the construction designated member recorded in the corrected construction plan database over member coordinates and a member shape linked by member identification information of the construction designated member in the design database.

18. The management system according to claim 11, further comprising: a corrected construction plan reflecting unit configured to newly add the construction designated member, the construction designated member coordinates, and the construction designated member shape recorded in the corrected construction plan database into the design database.
